(19) United States
(12) Patent Application Publication
(10) Pub. No.: US 2025/0379607 A1
(43) Pub. Date: Dec. 11, 2025

(54) HIGH-FREQUENCY MODULE AND COMMUNICATION DEVICE

(71) Applicant: Murata Manufacturing Co., Ltd., Nagaokakyo-shi (JP)

(72) Inventor: Daisuke YOSHIDA, Nagaokakyo-shi (JP)

(73) Assignee: Murata Manufacturing Co., Ltd., Nagaokakyo-shi (JP)

(21) Appl. No.: 19/307,147

(22) Filed: Aug. 22, 2025

Related U.S. Application Data
(63) Continuation of application No. PCT/JP2024/009489, filed on Mar. 12, 2024.

(30) Foreign Application Priority Data
Mar. 30, 2023 (JP) 2023-056737

(51) Int. Cl. H04B 1/18; H03F 3/68; H03H 7/38

(52) U.S. Cl. CPC H04B 1/18; H03F 3/68; H03H 7/38; H03F 2200/294

(57) ABSTRACT

A high-frequency module includes a mounting substrate and a plurality of reception paths. Each reception path includes a reception filter and a matching circuit. Each matching circuit includes an inductor and a low-noise amplifier. In each of the plurality of reception paths, the reception filter is connected to the low-noise amplifier through a respective matching circuit. At least one of the plurality of matching circuits includes, as the inductor, a chip inductor and an inner layer inductor built in the mounting substrate.

### CROSS-REFERENCE TO RELATED APPLICATIONS

The present application is a continuation of International Application No. PCT/JP2024/009489, filed Mar. 12, 2024, which claims priority to Japanese patent application JP 2023-056737, filed Mar. 30, 2023, the entire contents of each of which being incorporated herein by reference.

### TECHNICAL FIELD

The present disclosure relates to a high-frequency module and communication device, and more particularly to a high-frequency module and communication device having a plurality of reception paths.

### BACKGROUND ART

Patent Document 1 discloses a high-frequency module having a plurality of reception paths. In the high-frequency module of Patent Document 1, a low-noise amplifier and a filter are disposed in each reception path, and an inductor is disposed between the output end of the filter and the input end of the low-noise amplifier. The inductor constitutes a matching circuit that matches the output impedance of the filter and the input impedance of the low-noise amplifier.

### CITATION LIST

### Patent Document

Patent Document 1: Japanese Unexamined Patent Application Publication No. 2022-99532

### SUMMARY

### Technical Problems

In a high-frequency module having a plurality of reception paths, the frequency of the signal passing through each reception path is generally different. Further, the inductance of the matching circuit provided in the reception path depends on the frequency of the signal passing through the reception path.

However, if it is tried to increase the inductance of the matching circuit, it is necessary to increase the size of the inductor used in the matching circuit. On the other hand, if it is tried to increase the inductance of the matching circuit while suppressing the size of the inductor, the resistive component of the matching circuit may become large. When the resistive component of the matching circuit becomes large, the noise factor of the low-noise amplifier will become large.

Therefore, in a conventional high-frequency module, if it is tried to set the inductance and resistive component of the matching circuit to appropriate values, it is necessary to use a large inductor, which may make it difficult to miniaturize the high-frequency module.

The present disclosure is directed to providing, in a high-frequency module having a plurality of reception paths, a high-frequency module and a communication device capable of achieving both miniaturization of the high-frequency module and reduction of the noise factor of the low-noise amplifier.

### Solutions to Problems

A high-frequency module according to one aspect of the present disclosure has a plurality of reception paths. The high-frequency module includes a mounting substrate, a plurality of reception filters, a plurality of matching circuits, and at least one low-noise amplifier. The plurality of reception filters are disposed respectively in the plurality of reception paths. The plurality of matching circuits are disposed respectively in the plurality of reception paths, each matching circuit including an inductor. The at least one low-noise amplifier is connected to each of the plurality of reception paths. In each of the plurality of reception paths, the reception filter and the at least one low-noise amplifier is connected to each other with the matching circuit disposed in the said reception path interposed therebetween. At least one of the plurality of matching circuits includes, as the inductor, a chip inductor and an inner layer inductor. The chip inductor is disposed on the mounting substrate. The inner layer inductor is built in the mounting substrate.

The communication device according to another aspect of the present disclosure includes the high-frequency module and a signal processing circuit. The signal processing circuit is connected to the high-frequency module.

### Advantageous Effects

With the high-frequency module and the communication device according to the above aspects of the present disclosure, both miniaturization of the high-frequency module and reduction of the noise factor of the low-noise amplifier can be achieved.

### BRIEF DESCRIPTION OF DRAWINGS

FIG. 1 is a circuit configuration diagram of a high-frequency module according to Embodiment 1.

FIG. 2 is a plan view of the high-frequency module according to Embodiment 1.

FIG. 3 is a sectional view of the high-frequency module taken along line X-X of FIG. 2.

FIG. 4 is a bottom view of the high-frequency module according to Embodiment 1.

FIG. 5 is a circuit configuration diagram of a communication device including the high-frequency module according to Embodiment 1.

FIG. 6 is a plan view of a high-frequency module according to Modification 1 of Embodiment 1.

FIG. 7 is a plan view of a high-frequency module according to Modification 2 of Embodiment 1.

FIG. 8 is a circuit configuration diagram of a high-frequency module according to Embodiment 2.

FIG. 9 is a circuit configuration diagram of a high-frequency module according to Embodiment 3.

FIG. 10 is a circuit configuration diagram of a high-frequency module according to Embodiment 4.

FIG. 11 is a plan view of the high-frequency module according to Embodiment 4.

### DESCRIPTION OF EMBODIMENTS

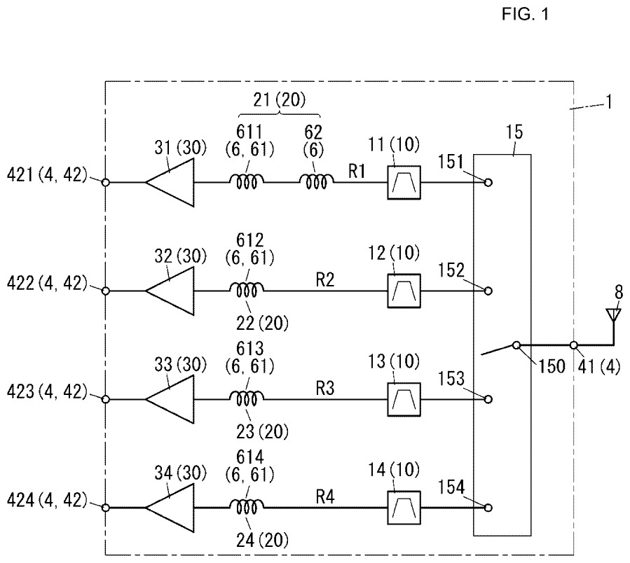

Hereinafter, high-frequency modules and communication devices according to Embodiments 1 to 4 and modifications will be described with reference to the drawings. FIGS. 1 to 11, to which the following embodiments and the like are referred, are schematic diagrams, and the ratios of the size and thickness of the components shown in these drawings do not necessarily reflect the actual dimensional ratios.

### Embodiment 1

The configuration of a high-frequency module 1 according to Embodiment 1 will be described with reference to the drawings.

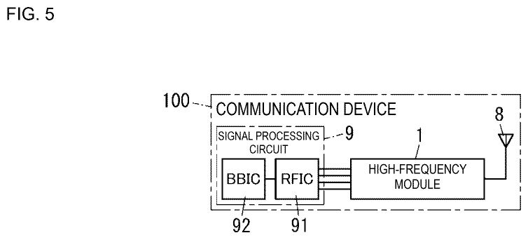

As shown in FIG. 5, the high-frequency module 1 is used for a communication device 100, for example. The communication device 100 is, for example, a mobile phone such as a smartphone. Note that the communication device 100 is not limited to a mobile phone, and may be, for example, a wearable terminal such as a smartwatch. The high-frequency module 1 is, for example, a high-frequency module compatible with 4G (4th generation mobile communication) standards, 5G (5th generation mobile communication) standards, and the like. The 4G standard is, for example, a 3GPP (registered trademark, Third Generation Partnership Project) LTE (registered trademark, Long Term Evolution) standard. The 5G standard is, for example, 5G NR (New Radio).

The communication device 100 receives, for example, a reception signal. Noted that the communication device 100 may include a transmission module (not shown) that performs transmission, and may transmit a transmission signal. When the communication device 100 transmits a transmission signal, the communication device 100 switches transmission and reception in a time division manner, for example. When the reception signal and the transmission signal are signals of the same frequency band, they are TDD (Time Division Duplex) signals. TDD is a wireless communication technology in which the same frequency band is assigned to the transmission and the reception in wireless communication, and the transmission and the reception are performed while the transmission and the reception are switched in a time-division manner. Note that a part of the transmission signal and the reception signal of the communication device 100 may be FDD (Frequency Division Duplex) signals. FDD is a wireless communication technology in which different frequency bands are assigned to the transmission and the reception in wireless communication to perform the transmission and the reception.

### (1) Circuit Configuration of High-Frequency Module

As shown in FIG. 1, the high-frequency module 1 according to Embodiment 1 has a plurality (four in the example illustrated in the drawings) of reception paths R1 to R4. As shown in FIG. 1, the high-frequency module 1 includes a plurality (four in the example illustrated in the drawings) of reception filters 10, a plurality (four in the example illustrated in the drawings) of matching circuits 20, and a plurality (four in the illustrated example) of low-noise amplifiers 30. Each of the plurality of matching circuits 20 includes one or more inductors 6. For example, each of the plurality of matching circuits 20 includes an inductive element for impedance matching. This inductive element may be a single inductor component or a composite inductor formed from a plurality of inductor components connected together. The high-frequency module 1 further includes a switch 15 and a plurality (four in the example illustrated in the drawings) of external connection terminals 4. The plurality of external connection terminals 4 includes an antenna terminal 41 and a plurality (four in the example illustrated in the drawings) of signal output terminals 42.

### (1.1) Reception Filters

Each of the plurality of reception filters 10 is a filter for passing a reception signal. In the high-frequency module 1 according to Embodiment 1, the plurality of reception filters 10 includes a reception filter 11, a reception filter 12, a reception filter 13, and a reception filter 14. The plurality of reception filters 10 correspond to the plurality of reception paths R1 to R4, respectively. More specifically, the reception filter 11 corresponds to the reception path R1. The reception filter 12 corresponds to the reception path R2. The reception filter 13 corresponds to the reception path R3. The reception filter 14 corresponds to the reception path R4.

The plurality of reception filters 10 have mutually different pass bands and stop bands. Here, the pass band refers to a frequency band in which the loss of the signal passing through the reception filter 10 is within 3 dB with respect to the minimum value of the loss of the signal passing through the reception filter 10. More specifically, the reception filter 11 takes the reception band of a first communication band as its pass band, and takes the reception band of each of second to fourth communication bands as its stop band. The reception filter 12 takes the reception band of the second communication band as its pass band, and takes the reception band of each of the first, third, and fourth communication bands as its stop band. The reception filter 13 takes the reception band of the third communication band as its pass band, and takes the reception band of each of the first, second, and fourth communication bands as its stop band. The reception filter 14 takes the reception band of the fourth communication band as its pass band, and takes the reception band of each of the first to third communication bands as its stop band. The frequency of the reception band of each of the first to fourth communication bands becomes higher in the order of: the first communication band, the second communication band, the third communication band, and the fourth communication band. That is, among the plurality of reception filters 10, the reception filter 11 has the lowest frequency of the pass band.

Each of the plurality of reception filters 10 is connected to the switch 15. Each of the plurality of reception filters 10 is connected to a corresponding one of the low-noise amplifiers 30. Here, the low-noise amplifier 30 corresponding to each of the reception filters 10 refers to one low-noise amplifier 30 connected to each of the reception filters 10. In the high-frequency module 1 according to Embodiment 1, the plurality of low-noise amplifiers 30 includes a low-noise amplifier 31, a low-noise amplifier 32, a low-noise amplifier 33, and a low-noise amplifier 34.

In the high-frequency module 1 according to Embodiment 1, the plurality of reception filters 10 and the plurality of low-noise amplifier 30 correspond one-to-one with each other. More specifically, the reception filter 11 corresponds to the low-noise amplifier 31. The reception filter 11 is provided between the low-noise amplifier 31 and the switch 15. The reception filter 12 corresponds to the low-noise amplifier 32. The reception filter 12 is provided between the low-noise amplifier 32 and the switch 15. The reception filter 13 corresponds to the low-noise amplifier 33. The reception filter 13 is provided between the low-noise amplifier 33 and the switch 15. The reception filter 14 corresponds to the low-noise amplifier 34. The reception filter 14 is provided between the low-noise amplifier 34 and the switch 15.

### (1.2) Low-Noise Amplifier

Each of the plurality of low-noise amplifiers 30 is an amplifier that amplifies a reception signal with low noise. Each of the plurality of low-noise amplifiers 30 is provided between a corresponding one of the reception filters 10 and a corresponding one of the signal output terminals 42. Here, the signal output terminal 42 corresponding to each of the plurality of reception filters 10 refers to one signal output terminal 42 connected to the low-noise amplifier 30 corresponding to each of the plurality of reception filters 10. The plurality of low-noise amplifiers 30 and the plurality of signal output terminals 42 correspond one-to-one with each other. Here, in the high-frequency module 1 according to Embodiment 1, the plurality of signal output terminals 42 include a signal output terminal 421, a signal output terminal 422, a signal output terminal 423, and a signal output terminal 424.

More specifically, the low-noise amplifier 31 is provided between the reception filter 11 and the signal output terminal 421. The low-noise amplifier 32 is provided between the reception filter 12 and the signal output terminal 422. The low-noise amplifier 33 is provided between the reception filter 13 and the signal output terminal 423. The low-noise amplifier 34 is provided between the reception filter 14 and the signal output terminal 424.

Each of the plurality of low-noise amplifiers 30 has an input terminal (not shown) and an output terminal (not shown). The input terminal of the low-noise amplifier 30 is connected to a corresponding one of the reception filters 10. The output terminal of the low-noise amplifier 30 is connected to an external circuit (for example, a signal processing circuit) with a corresponding one of the signal output terminal 42 interposed therebetween.

### (1.3) SWITCHES

The switch 15 is a switch for switching the reception paths R1 to R4 connected to the antenna terminal 41. The switch 15 has a common terminal 150 and a plurality of (four in the example illustrated in the drawings) selection terminals 151, 152, 153, and 154. The common terminal 150 is connected to the antenna terminal 41.

The selection terminal 151 is connected to the reception filter 11. In the high-frequency module 1 according to Embodiment 1, the signal path between the selection terminal 151 of the switch 15 and the signal output terminal 421 is the reception path R1.

The selection terminal 152 is connected to the reception filter 12. In the high-frequency module 1 according to Embodiment 1, the signal path between the selection terminal 152 of the switch 15 and the signal output terminal 422 is the reception path R2.

The selection terminal 153 is connected to the reception filter 13. In the high-frequency module 1 according to Embodiment 1, the signal path between the selection terminal 153 of the switch 15 and the signal output terminal 423 is the reception path R3.

The selection terminal 154 is connected to the reception filter 14. In the high-frequency module 1 according to Embodiment 1, the signal path between the selection terminal 154 of the switch 15 and the signal output terminal 424 is the reception path R4.

### (1.4) Matching Circuits

Each of the plurality of matching circuits 20 is a circuit for matching the impedance of the reception filter 10 connected via the matching circuit 20 with the impedance of the low-noise amplifier 30 corresponding to the reception filter 10. Each of the plurality of matching circuits 20 includes the inductor 6.

Each of the plurality of matching circuits 20 is provided in a corresponding one of the reception paths R1 to R4. The plurality of matching circuits 20 are disposed in the reception paths R1 to R4, respectively. Each of the plurality of matching circuits 20 is connected, in a corresponding one of the reception paths R1 to R4, between the reception filter 10 and the low-noise amplifier 30. The plurality of matching circuits 20 includes a matching circuit 21, a matching circuit 22, a matching circuit 23, and a matching circuit 24. The matching circuit 21 corresponds to the reception path R1. That is, the matching circuit 21 is provided, in the reception path R1, between the reception filter 11 and the low-noise amplifier 31. The matching circuit 22 corresponds to the reception path R2. That is, the matching circuit 22 is provided, in the reception path R2, between the reception filter 12 and the low-noise amplifier 32. The matching circuit 23 corresponds to the reception path R3. That is, the matching circuit 23 is provided, in the reception path R3, between the reception filter 13 and the low-noise amplifier 33. The matching circuit 24 corresponds to the reception path R4. That is, the matching circuit 24 is provided, in the reception path R4, between the reception filter 14 and the low-noise amplifier 34.

In each of the plurality of matching circuits 20, the higher the frequency of the pass band of the connected reception filter 10, the smaller the appropriate inductance; conversely, the lower the frequency of the pass band of the connected reception filter 10, the larger the appropriate inductance. As described above, in the high-frequency module 1 according to Embodiment 1, the frequency of the pass band of the plurality of reception filters 10 increases in the order of: the reception filter 11, the reception filter 12, the reception filter 13, and the reception filter 14. Therefore, in the high-frequency module 1, the appropriate inductance of the plurality of matching circuits 20 increases in the order of: the matching circuit 24, the matching circuit 23, the matching circuit 22, and the matching circuit 21. For example, the inductance of the matching circuit 24 is 18 nH. Also, for example, the inductance of the matching circuit 23 is 22 nH. Also, for example, the inductance of the matching circuit 22 is 27 nH. Also, for example, the inductance of the matching circuit 21 is 36 nH.

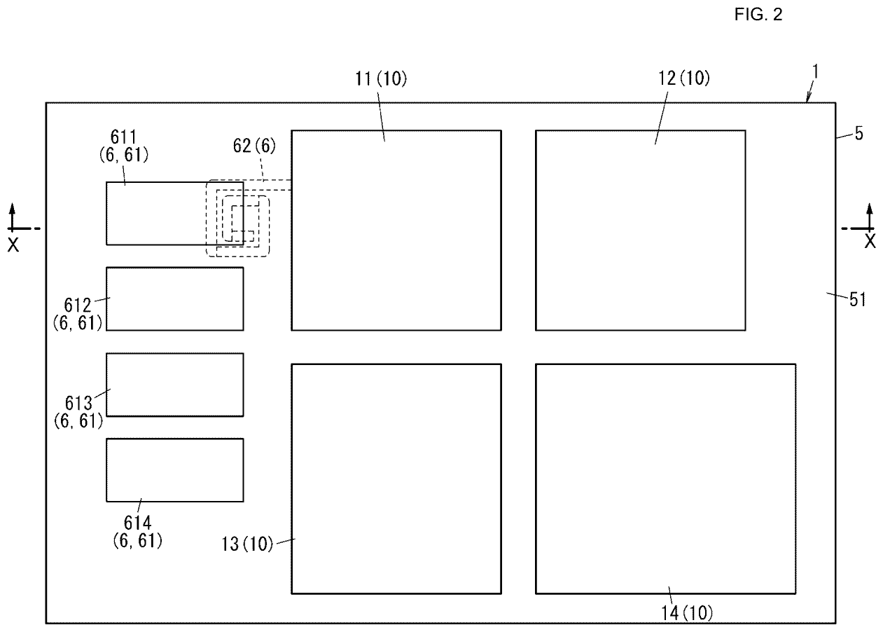

Among the plurality of matching circuits 20, at least one matching circuit 20 includes a chip inductor 61 and an inner layer inductor 62. The chip inductor 61 is disposed on a mounting substrate 5 (see FIGS. 2 to 4). The inner layer inductor 62 is built in the mounting substrate 5. The details will be described later. In the high-frequency module 1 according to Embodiment 1, the matching circuit 21 that includes the chip inductor 61 and the inner layer inductor 62 is, among the plurality of matching circuits 20, a matching circuit 20 having the largest inductance. The matching circuit 21, which is the at least one matching circuit 20, is provided in the reception path R1 through which the signal with the lowest frequency passes.

More specifically, the matching circuit 21 includes a chip inductor 611 and the inner layer inductor 62 connected in series. The inductance of the chip inductor 611 is 27 nH. The inductance of the inner layer inductor 62 is 9 nH. In other words, the inductance of the chip inductor 611 may be at least twice, e.g., three times, the inductance of the inner layer inductor 82. The matching circuit 22 includes a chip inductor 612 whose inductance is 27 nH. The matching circuit 23 includes a chip inductor 613 whose inductance is 22 nH. The matching circuit 24 includes a chip inductor 614 whose inductance is 18 nH.

To increase the inductance of an inductor, it is necessary to increase at least one of the number of turns of the coil and the cross-sectional area of the coil. Therefore, in order to increase the inductance without changing the size of each of the plurality of chip inductors 61, when there is no room to increase the cross-sectional area, it is necessary to increase the number of turns of the coil without increasing the volume of the conducting wire, so that the conducting wire may have to be made thinner and longer. Therefore, when the sizes of the plurality of chip inductors 61 are the same, the chip inductor 61 having a large inductance may have a larger resistive component than the chip inductor 61 having a small inductance. When the resistive component of the chip inductor 61 increases to thereby cause the resistance value of the matching circuit 20 to increase, the noise factor of the low-noise amplifier 30 connected to the matching circuit 20 may deteriorate.

However, in the high-frequency module 1 according to Embodiment 1, the inductance of the chip inductor 611 is equal to or less than the inductance of the chip inductor 612. Therefore, the resistance value of the chip inductor 611 and the resistance value of the chip inductor 612 can be made substantially the same. Thus, in the high-frequency module 1 according to Embodiment 1, the increase of the resistance value of the matching circuit 21 can be reduced without increasing the size of the chip inductor 61.

Also, to increase the inductance of the inner layer inductor 62, it is necessary to increase at least one of the number of turns of the coil and the cross-sectional area of the coil. Therefore, in order to reduce the resistance value of the inner layer inductor 62, the inductance of the inner layer inductor 62 is smaller than the inductance of the chip inductor 611 connected to the inner layer inductor 62. In other words, the inductance of the chip inductor 611 connected to the inner layer inductor 62 is larger than the inductance of the inner layer inductor 62.

### (1.5) External Connection Terminals

The plurality of external connection terminals 4 are terminals for electrically connecting to an external circuit (for example, a signal processing circuit 9 shown in FIG. 5). The plurality of external connection terminals 4 include the antenna terminal 41, the plurality of signal output terminals 42, a plurality of control terminals (not shown), and a plurality of ground terminals (not shown).

An antenna 8 is connected to the antenna terminal 41. In the high-frequency module 1, the antenna terminal 41 is connected to the common terminal 150 of the switch 15.

Each of the signal output terminals 42 is a terminal for outputting a reception signal from the high-frequency module 1 to an external circuit (for example, the signal processing circuit 9). As described above, in the high-frequency module 1, each of the signal output terminals 42 is connected to a corresponding one of the low-noise amplifiers 30.

The plurality of control terminals are terminals for inputting a control signal from an external circuit (for example, the signal processing circuit 9) to the high-frequency module 1.

The plurality of ground terminals are terminals that are electrically connected to a ground electrode of an external substrate (not shown) provided in the communication device 100, so that a ground potential is applied to the plurality of ground terminals. In the high-frequency module 1, the plurality of ground terminals are connected to a ground layer (not shown) of the mounting substrate 5 (see FIGS. 2 to 4).

### (2) Structure of High-Frequency Module

Next, the structure of the high-frequency module 1 according to Embodiment 1 will be described.

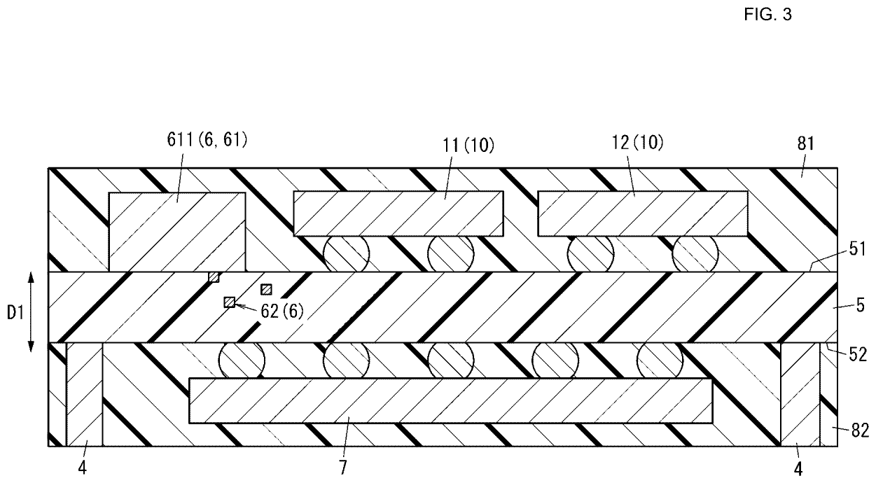

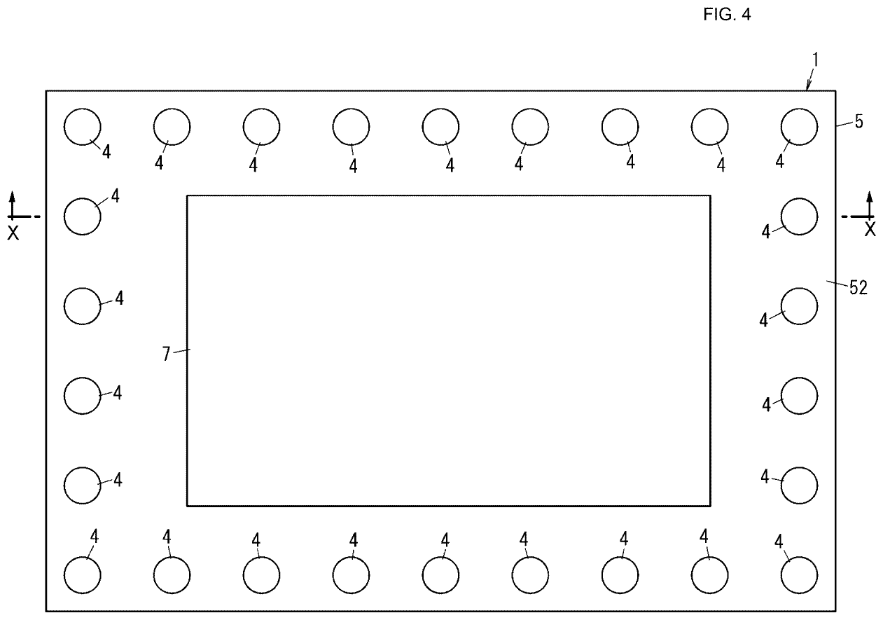

As shown in FIGS. 2 to 4, the high-frequency module 1 includes the mounting substrate 5. Further, as shown in FIGS. 2 and 3, the high-frequency module 1 includes the plurality of (four in the example illustrated in the drawings) reception filters 10, the plurality of (four in the example illustrated in the drawings) chip inductors 61, and at least one (one in the example illustrated in the drawings) inner layer inductor 62. Further, as shown in FIGS. 3 and 4, the high-frequency module 1 includes an IC chip 7. The IC chip 7 includes the switch 15 and the plurality of (four in FIG. 1) low-noise amplifiers 30. Further, as shown in FIG. 3, the high-frequency module 1 includes a first resin layer 81 and a second resin layer 82. Note that the first resin layer 81 is not shown in FIG. 2. Note that the second resin layer 82 is not shown in FIG. 4.

The high-frequency module 1 can be electrically connected to an external substrate (not shown). The external substrate corresponds to, for example, the motherboard of the communication device 100 such as a mobile phone or a communication apparatus. When the high-frequency module 1 can be electrically connected to the external substrate, it includes not only a case where the high-frequency module 1 is directly mounted on the external substrate but also a case where the high-frequency module 1 is indirectly mounted on the external substrate. Examples of the case where the high-frequency module 1 is indirectly mounted on the external substrate includes a case where the high-frequency module 1 is mounted on another high-frequency module mounted on the external substrate.

### (2.1) Mounting Substrate

As shown in FIG. 3, the mounting substrate 5 has a first main surface 51 and a second main surface 52. The first main surface 51 and the second main surface 52 face each other in the thickness direction (a first direction D1) of the mounting substrate 5. When the high-frequency module 1 is mounted on the external substrate, the second main surface 52 faces a main surface of the external substrate on the side of the mounting substrate 5. The mounting substrate 5 is, for example, a double-sided mounting substrate to which electronic components can be mounted on each of the first main surface 51 and the second main surface 52.

The mounting substrate 5 is a multilayer substrate including a plurality of dielectric layers and a plurality of conductive layers. The plurality of dielectric layers and the plurality of conductive layers are laminated in the first direction D1. The plurality of conductive layers are formed in a predetermined pattern defined for each layer. Each of the plurality of conductive layers includes one or more conductor portions in a plane orthogonal to the first direction D1. The material of each conductive layer is, for example, copper. The plurality of conductive layers include a ground layer. In the high-frequency module 1, the plurality of ground terminals and the ground layer are electrically connected to each other with a via conductor or the like of the mounting substrate 5 interposed therebetween. The mounting substrate 5 is, for example, an LTCC (Low Temperature Co-fired Ceramics) substrate. The mounting substrate 5 is not limited to an LTCC substrate, but may alternatively be, for example, a printed wiring board, an HTCC (High Temperature Co-fired Ceramics) substrate, or a resin multilayer substrate.

Further, the mounting substrate 5 is not limited to an LTCC substrate, but may alternatively be, for example, a wiring structure. The wiring structure is, for example, a multilayer structure. The multilayer structure includes at least one insulating layer and at least one conductive layer. The insulating layer is formed in a predetermined pattern. When there are a plurality of insulating layers, the plurality of insulating layers are formed in a predetermined pattern defined for each layer. The conductive layer is formed in a predetermined pattern different from the predetermined pattern of the insulating layer. When there are a plurality of conductive layers, the plurality of conductive layers are formed in a predetermined pattern defined for each layer. The conductive layer may include one or more rewiring portions. In the wiring structure, a first surface of two surfaces facing each other in the thickness direction of the multilayer structure is the first main surface 51 of the mounting substrate 5, and a second surface is the second main surface 52 of the mounting substrate 5. The wiring structure may be, for example, an interposer. The interposer may be an interposer using a silicon substrate, or a multi-layered substrate.

The first main surface 51 and the second main surface 52 of the mounting substrate 5 are separated in the first direction D1, and intersect the first direction D1. The first main surface 51 of the mounting substrate 5 may be, for example, orthogonal to the first direction D1, but include, for example, a side surface or the like of the conductor portion, as a surface not orthogonal to the first direction D1. The second main surface 52 of the mounting substrate 5 may be, for example, orthogonal to the first direction D1, but include, for example, a side surface of a conductor portion or the like as a surface not orthogonal to the first direction D1. The first main surface 51 and the second main surface 52 of the mounting substrate 5 may have fine irregularities, recesses, and/or projections.

The plurality of reception filters 10 and the plurality of chip inductors 61 are disposed on the first main surface 51 of the mounting substrate 5. The IC chip 7 and the plurality of external connection terminals 4 are disposed on the second main surface 52 of the mounting substrate 5.

### (2.2) Inductors

The plurality of chip inductors 61 are disposed on the first main surface 51 of the mounting substrate 5. More specifically, the plurality of chip inductors 61 are mounted close to each other on the first main surface 51 of the mounting substrate 5. Here, the expression “the plurality of chip inductors 61 are mounted close to each other on the first main surface 51 of the mounting substrate 5” means that no other component is disposed between one given chip inductor 61 and another chip inductor 61 nearest to the given inductor 61. Thus, the variation of the wiring length between each of the plurality of chip inductors 61 and the IC chip 7 disposed on the second main surface 52 of the mounting substrate 5 can be reduced. Therefore, in each of the reception paths R1 to R4, the internal resistance and parasitic capacitance generated by the wiring line between the chip inductor 61 and the low-noise amplifier 30 included in the IC chip 7 can be reduced. Therefore, the variation of the noise factor of the low-noise amplifier 30 in the reception paths R1 to R4 can be reduced.

The inner layer inductor 62 is built in the mounting substrate 5. Here, the expression “the inner layer inductor 62 is built in the mounting substrate 5” means that the inner layer inductor 62 is disposed inside the mounting substrate 5. Note that the inner layer inductor 62 may alternatively be mounted on at least one of the first main surface 51 and the second main surface 52 of the mounting substrate 5. Further, the inner layer inductor 62 may alternatively be disposed inside the mounting substrate 5 in a state where a portion thereof is exposed to at least one of the first main surface 51 and the second main surface 52 of the mounting substrate 5. In the high-frequency module 1 according to Embodiment 1, the inner layer inductor 62 is disposed inside the mounting substrate 5. The inner layer inductor 62 includes one or more conductor portions. More specifically, the inner layer inductor 62 includes a plurality of conductor portions and a via conductor. The plurality of conductor portions are formed in a L-shape when viewed in plan view in the thickness direction (first direction D1) of the mounting substrate 5. The plurality of conductor portions are disposed so that the inner layer inductor 62 as a whole becomes a spiral shape when viewed in plan view in the thickness direction (first direction D1) of the mounting substrate 5. In the inner layer inductor 62, since it is easier to increase the cross-sectional area of the coil and to increase the cross-sectional area of the conductor portion than in the chip inductor 61, it is possible to achieve an inductor with low internal resistance.

When viewed in plan view in the thickness direction (first direction D1) of the mounting substrate 5, a portion of the inner layer inductor 62 overlaps with a portion of the chip inductor 611. With such a configuration, the area occupied by the matching circuit 21 when viewed in plan view in the thickness direction (first direction D1) of the mounting substrate 5 can be reduced, so that the high-frequency module 1 can be easily miniaturized. Other configurations are also possible as long as at least a portion of the chip inductor 611 overlaps with a portion of the inner layer inductor 62, such as a configuration in which all of the chip inductor 612 overlaps with a portion of the inner layer inductor 62. When viewed in plan view in the thickness direction (first direction D1) of the mounting substrate 5, the inner layer inductor 62 does not overlap with the chip inductors 612 to 614. More specifically, when viewed in plan view in the thickness direction (first direction D1) of the mounting substrate 5, the inner layer inductor 62 does not overlap with any of the chip inductors 612 to 614. With such a configuration, the electromagnetic coupling between the inner layer inductor 62 and the chip inductors 612 to 614 can be suppressed, so that the isolation between each of the reception paths R1 to R4 is improved.

### (2.3) Reception Filters

The plurality of reception filters 10 are disposed on the first main surface 51 of the mounting substrate 5. More specifically, the plurality of reception filters 10 are disposed between the plurality of chip inductors 61 and the end of the first main surface 51 of the mounting substrate 5. Each of the plurality of reception filters 10 is, for example, an acoustic wave filter using a surface acoustic wave (SAW). Note that the acoustic wave filter may alternatively be an acoustic wave filter using a bulk acoustic wave (BAW) or a film bulk acoustic wave (FBAR).

### (2.4) IC Chip

The IC chip 7 is disposed on the second main surface 52 of the mounting substrate 5. As shown in FIGS. 2 to 4, when viewed in plan view in the thickness direction (first direction D1) of the mounting substrate 5, the IC chip 7 overlaps with the plurality of inductors 6. More specifically, when viewed in plan view in the thickness direction (first direction D1) of the mounting substrate 5, at least a portion of the IC chip 7 overlaps at least a portion of at least one of the plurality of inductors 6. With such a configuration, the wiring length between at least one of the plurality of chip inductors 61 and the IC chip 7 can be reduced. Therefore, the resistance value can be reduced for at least one of the reception paths R1 to R4.

### (2.5) External Connection Terminals

The plurality of external connection terminals 4 are terminals for electrically connecting the mounting substrate 5 and an external substrate (not shown).

The plurality of external connection terminals 4 are disposed on the second main surface 52 of the mounting substrate 5. The plurality of external connection terminals 4 are columnar (e.g. cylindrical) electrodes provided on the second main surface 52 of the mounting substrate 5. The material of the plurality of external connection terminals 4 is, for example, metal (for example, copper, a copper alloy, or the like).

### (2.6) First Resin Layer

As shown in FIG. 3, the first resin layer 81 is disposed on the first main surface 51 of the mounting substrate 5. The first resin layer 81 covers the plurality of reception filters 10 and the plurality of chip inductors 61. The first resin layer 81 contains a resin (for example, epoxy resin). The first resin layer 81 may contain a filler in addition to the resin.

### (2.7) Second Resin Layer

As shown in FIG. 3, the second resin layer 82 is disposed on the second main surface 52 of the mounting substrate 5. The second resin layer 82 covers the IC chip 7. When a part or all of the inner layer inductor 62 is disposed on the second main surface 52, the second resin layer 82 covers the inner layer inductor 62. The second resin layer 82 contains a resin (for example, epoxy resin). The second resin layer 82 may contain a filler in addition to the resin. The material of the second resin layer 82 may be the same or different from the material of the first resin layer 81.

### (3) Communication Device

As shown in FIG. 5, the communication device 100 includes the high-frequency module 1, the antenna 8, and the signal processing circuit 9. The communication device 100 further includes an external substrate (not shown) on which the high-frequency module 1 is mounted. The external substrate is, for example, a printed circuit board. The external substrate has a ground electrode to which a ground potential is applied.

### (3.1) Antenna

As shown in FIG. 1, the antenna 8 is connected to the antenna terminal 41 of the high-frequency module 1. The antenna 8 has a reception function of receiving a reception signal, as a radio wave, from the outside and outputting the received signal to the high-frequency module 1.

### (3.2) Signal Processing Circuit

As shown in FIG. 5, the signal processing circuit 9 includes an RF signal processing circuit 91 and a baseband signal processing circuit 92. The signal processing circuit 9 processes a signal passing through the high-frequency module 1. More specifically, the signal processing circuit 9 processes the reception signal.

The RF signal processing circuit 91 is, for example, an RFIC (Radio Frequency Integrated Circuit). The RF signal processing circuit 91 performs signal processing on a high-frequency signal.

The RF signal processing circuit 91 performs signal processing, such as down-conversion processing, on the reception signal output from the high-frequency module 1, and outputs the reception signal having undergone the signal processing to the baseband signal processing circuit 92.

The baseband signal processing circuit 92 is, for example, a BBIC (Baseband Integrated Circuit). The reception signal processed by the baseband signal processing circuit 92 is, for example, used as an image signal for image display or as an audio signal for audio communication.

Further, the RF signal processing circuit 91 functions as a control unit that controls the switch 15 of the high-frequency module 1. Specifically, the RF signal processing circuit 91 switches the connection of the switch 15 of the high-frequency module 1 according to a control signal (not shown). Note that the control unit may be provided outside the RF signal processing circuit 91. For example, the control unit may be provided in the high-frequency module 1 or the baseband signal processing circuit 92.

### (4) Effects

The high-frequency module 1 according to Embodiment 1 includes a mounting substrate 5, a plurality of reception filters 10, a plurality of matching circuits 20, and a plurality of low-noise amplifiers 30. The plurality of reception filters 10 are disposed respectively in a plurality of reception paths R1 to R4. The plurality of matching circuits 20 are disposed respectively in the plurality of reception paths R1 to R4, and each includes an inductor. The plurality of low-noise amplifiers 30 are connected to each of the plurality of reception paths R1 to R4. In the respective plurality of reception paths R1 to R4, the plurality of reception filters 10 and the plurality of low-noise amplifiers 30 are connected to each other with the plurality of matching circuits 20 disposed in the plurality of reception paths R1 to R4 interposed therebetween. A matching circuit 21, which is at least one of the matching circuits 20, includes, as the inductor 6, a chip inductor 611 disposed in the mounting substrate 5 and an inner layer inductor 62 built in the mounting substrate 5.

In the high-frequency module 1 according to Embodiment 1, since the matching circuit 21 includes the inner layer inductor 62, the resistance value of the matching circuit 21 can be reduced without increasing the size of the chip inductor 611. Therefore, both miniaturization of the high-frequency module 1 and reduction of the noise factor of the low-noise amplifier 30 can be achieved.

In the high-frequency module 1 according to Embodiment 1, among the plurality of matching circuits 20, the matching circuit 21 having the largest inductance includes the chip inductor 611 and the inner layer inductor 62. Therefore, the chip inductor 611 having the smallest inductance can be used for the matching circuit 21 having the largest inductance, among the plurality of matching circuits 20. Therefore, the high-frequency module 1 can be miniaturized. Further, in the high-frequency module 1, since the resistive component of the chip inductor 61 can be reduced, the resistance value of any of the plurality of matching circuits 20 can be reduced. Thus, the noise factor of the low-noise amplifier 30 can be improved in any of the plurality of reception paths R1 to R4. Further, among the plurality of matching circuits 20, the matching circuit 21 is disposed in the reception path R1 through which a signal having the lowest frequency passes. Therefore, since the matching circuit 21 disposed in the reception path R1, which tends to have a large inductance, includes the inner layer inductor 62, the inductance of the chip inductor 611 can be reduced.

Further, in the high-frequency module 1 according to Embodiment 1, the inductance of the chip inductor 611 is equal to or less than the inductance of the chip inductor 612 included in a matching circuit 22. Therefore, the difference between the resistance value of the chip inductor 611 in the matching circuit 21 and the resistance value of the chip inductor 612 in the matching circuit 22 can be reduced. Therefore, it becomes easy to align, among the plurality of matching circuits 20, the resistance value of the matching circuit 20 to small value. Thus, the noise factor of the low-noise amplifier 30 can be improved in any of the plurality of reception paths R1 to R4.

Further, in the high-frequency module 1 according to Embodiment 1, the chip inductor 611 and the inner layer inductor 62 overlap with each other when viewed in plan view in the thickness direction (first direction D1) of the mounting substrate 5. For example, part of the inner layer inductor 62 may be between the chip inductor 611 and the IC 7. Thus, the area of the matching circuit 20 can be reduced when viewed in plan view in the thickness direction (first direction D1) of the mounting substrate 5. Therefore, the high-frequency module 1 can be miniaturized. Further, in the high-frequency module 1 according to Embodiment 1, the inner layer inductor 62 does not overlap with the chip inductors 612 to 614 of the matching circuits 22 to 24 when viewed in plan view in the thickness direction (first direction D1) of the mounting substrate 5. Thus, the electromagnetic coupling between the matching circuit 21 and the matching circuits 22 to 24 can be reduced. Therefore, the isolation between the reception paths R1 to R4 can be improved.

Further, in the high-frequency module 1 according to Embodiment 1, the inductance of the chip inductor 612 is larger than that of the inner layer inductor 62. Thus, the increase of the resistance value of the inner layer inductor 62 due to the lengthening of the conductor constituting the inner layer inductor 62 can be reduced. Therefore, the deterioration of the noise factor of the low-noise amplifier 31 due to large resistance value of the inner layer inductor 62 can be reduced.

In the high-frequency module 1 according to Embodiment 1, the inductors 6 of the plurality of matching circuits 20 are disposed close to each other on the first main surface 51 of the mounting substrate 5. Thus, it is easy to shorten the wiring line between the IC chip 7, which includes the low-noise amplifier 30, and the inductor 6 of the matching circuit 20 corresponding to the low-noise amplifier 30. Therefore, the resistance value of the matching circuit 20 can be reduced, and the lowering of the noise factor of the low-noise amplifier 30 can be reduced.

In the high-frequency module 1 according to Embodiment 1, the plurality of reception filters 10 are disposed between the end of the mounting substrate 5 and the plurality of inductors 6. Thus, it is easy to shorten the wiring line between each of the plurality of reception filters 10 and the inductor 6 of the matching circuit 20 corresponding to the reception filter 10. Therefore, the resistance value of the matching circuit 20 can be reduced, and the lowering of the noise factor of the low-noise amplifier 30 can be reduced.

In the high-frequency module 1 according to Embodiment 1, the plurality of low-noise amplifiers 30 are included in one IC chip 7 disposed on the second main surface 52 of the mounting substrate 5. When viewed in plan view in the thickness direction (first direction D1) of the mounting substrate 5, at least a part of the inductor 6 of the matching circuit 20 overlaps with at least a part of the IC chip 7. Thus, it is easy to shorten the wiring line between the IC chip 7, which includes the low-noise amplifier 30, and the inductor 6 of the matching circuit 20 corresponding to the low-noise amplifier 30. Therefore, the resistance value of the matching circuit 20 can be reduced, and the lowering of the noise factor of the low-noise amplifier 30 can be reduced.

### (5) Modifications

Modifications of Embodiment 1 will be described below as examples.

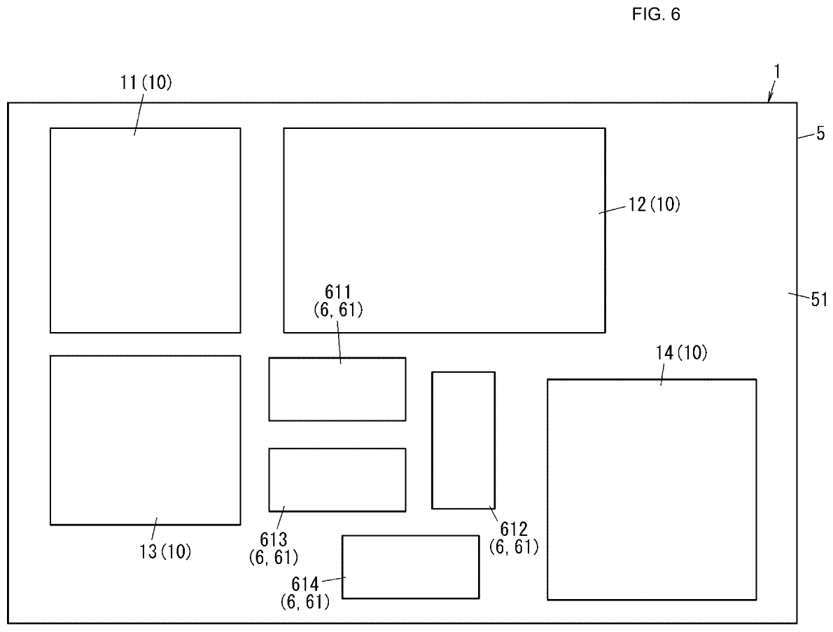

In a high-frequency module 1 according to Modification 1, the plurality of reception filters 10 and the plurality of chip inductors 61 are disposed on the first main surface 51 of the mounting substrate 5 as shown in FIG. 6. Note that the inner layer inductor 62 is not shown in FIG. 6. As shown in FIG. 6, the plurality of reception filters 10 are disposed so as to surround the plurality of chip inductors 61. Thus, it is easy to shorten the wiring line between the IC chip 7, which includes the plurality of low-noise amplifiers 30, and the chip inductor 61 of the matching circuit 20 corresponding to each of the plurality of low-noise amplifiers 30. The plurality of reception filters 10 are disposed between the end of the mounting substrate 5 and the plurality of chip inductors 61. Further, each of the plurality of reception filters 10 is disposed close to the connected chip inductor 61. Thus, it is easy to shorten the wiring line between each of the plurality of reception filters 10 and the chip inductor 61 corresponding to the reception filter 10. Therefore, the resistance value of the matching circuit 20 can be reduced, and the lowering of the noise factor of the low-noise amplifier 30 can be reduced.

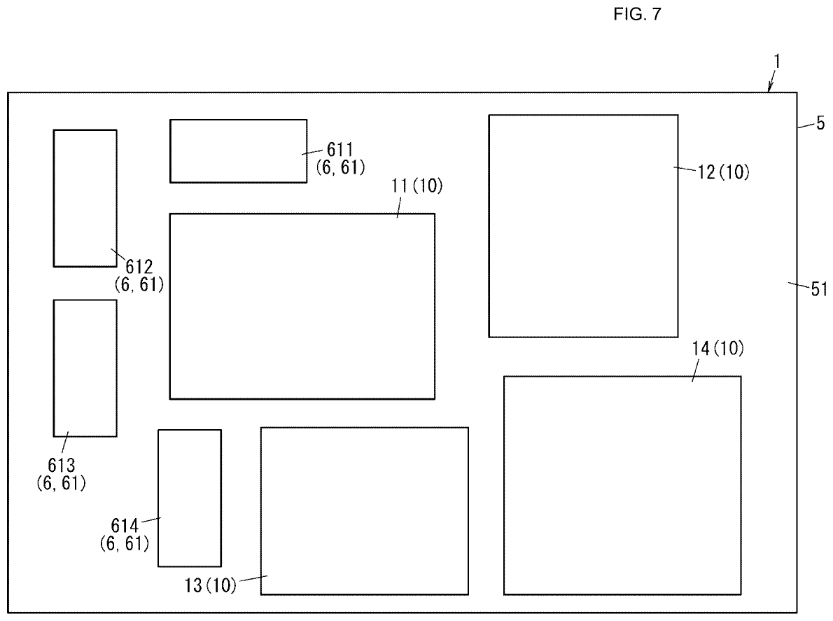

In a high-frequency module 1 according to Modification 2, the reception filter 10 and the chip inductor 61 are disposed on the first main surface 51 of the mounting substrate 5 as shown in FIG. 7. The inner layer inductor 62 is also not shown in FIG. 7. As shown in FIG. 7, the chip inductor 611 and the chip inductor 612 are disposed close to each other. The chip inductor 612 and the chip inductor 613 are disposed close to each other. The chip inductor 613 and the chip inductor 614 are disposed close to each other. Thus, it is easy to shorten the wiring line between the IC chip 7, which includes the low-noise amplifier 30, and the inductor 6 of the matching circuit 20 corresponding to the low-noise amplifier 30. The plurality of reception filters 10 are disposed between the end of the mounting substrate 5 and the plurality of chip inductors 61. Thus, it is easy to shorten the wiring line between each of the plurality of reception filters 10 and the chip inductor 61 corresponding to the reception filter 10. Therefore, the resistance value of the matching circuit 20 can be reduced, and the lowering of the noise factor of each of the plurality of low-noise amplifiers 30 can be reduced.

### Embodiment 2

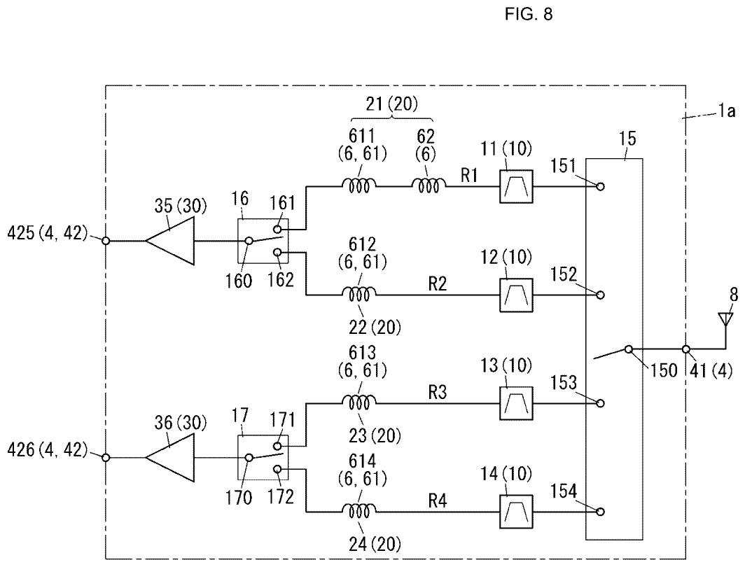

A high-frequency module 1a according to Embodiment 2 will be described with reference to FIG. 8. With respect to the high-frequency module 1a according to Embodiment 2, the same configurations as those of the high-frequency module 1 according to Embodiment 1 (see FIG. 1) are denoted by the same reference signs, and the description thereof will be omitted.

The high-frequency module 1a according to Embodiment 2 includes a low-noise amplifier 35 and a low-noise amplifier 36 as a plurality of low-noise amplifiers 30. The high-frequency module 1a according to Embodiment 2 includes a signal output terminal 425 and a signal output terminal 426 as a plurality of signal output terminals 42. As shown in FIG. 8, the high-frequency module 1a according to Embodiment 2 further includes a second switch 16 and a third switch 17 apart from the switch 15 (hereinafter referred to as a “first switch 15”). The second switch 16 and the third switch 17 are included in the IC chip 7, for example.

The second switch 16 is connected between the reception filters 11 and 12 and the low-noise amplifier 35. The second switch 16 includes a common terminal 160 and selection terminals 161 and 162. The common terminal 160 of the second switch 16 is connected to the low-noise amplifier 35. The selection terminal 161 of the second switch 16 is connected to the chip inductor 611. The selection terminal 162 of the second switch 16 is connected to the chip inductor 612.

In the high-frequency module 1a according to Embodiment 2, each of the reception filters 10 is connected to a corresponding one of the low-noise amplifiers 30. The reception filter 11 corresponds to the low-noise amplifier 35. The reception filter 12 corresponds to the low-noise amplifier 35. The reception filter 13 corresponds to the low-noise amplifier 36. The reception filter 14 corresponds to the low-noise amplifier 36.

In the high-frequency module 1a according to Embodiment 2, the reception path R1 is a path between the selection terminal 151 of the first switch 15 and the signal output terminal 425. In the high-frequency module 1a according to Embodiment 2, the reception path R2 is a path between the selection terminal 152 of the first switch 15 and the signal output terminal 425. That is, in the high-frequency module 1a according to Embodiment 2, both the reception path R1 and the reception path R2 include a path between the common terminal 160 of the second switch 16 and the signal output terminal 425. The second switch 16 is a switch to switch which of the reception filter 11 and the reception filter 12 is to be connected to the low-noise amplifier 35 and the signal output terminal 425.

In the high-frequency module 1a according to Embodiment 2, the chip inductor 611 and the inner layer inductor 62 are connected, in the reception path R1, between the reception filter 11 and the low-noise amplifier 35. That is, in the high-frequency module 1a according to Embodiment 2, the matching circuit 21 provided in the reception path R1 includes the chip inductor 611 and the inner layer inductor 62. On the other hand, in the high-frequency module 1a according to Embodiment 2, the chip inductor 612 is connected, in the reception path R2, between the reception filter 12 and the low-noise amplifier 35. That is, in the high-frequency module 1a according to Embodiment 2, the matching circuit 22 provided in the reception path R2 includes the chip inductor 612.

The third switch 17 is connected between the reception filters 13 and 14 and the low-noise amplifier 36. The third switch 17 includes a common terminal 170 and selection terminals 171 and 172. The common terminal 170 of the third switch 17 is connected to the low-noise amplifier 36. The selection terminal 171 of the third switch 17 is connected to the chip inductor 613. The selection terminal 172 of the third switch 17 is connected to the chip inductor 614.

In the high-frequency module 1a according to Embodiment 2, the reception path R3 is a path between the selection terminal 153 of the first switch 15 and the signal output terminal 426. In the high-frequency module 1a according to Embodiment 2, the reception path R4 is a path between the selection terminal 154 of the first switch 15 and the signal output terminal 426. That is, in the high-frequency module 1a according to Embodiment 2, both the reception path R3 and the reception path R4 include a path between the common terminal 170 of the third switch 17 and the signal output terminal 426. The second switch 17 is a switch to switch which of the reception filter 13 and the reception filter 14 is to be connected to the low-noise amplifier 36 and the signal output terminal 426.

In the high-frequency module 1a according to Embodiment 2, the chip inductor 613 is connected, in the reception path R3, between the reception filter 13 and the low-noise amplifier 36. That is, in the high-frequency module 1a according to Embodiment 2, the matching circuit 23 provided in the reception path R3 includes the chip inductor 613. On the other hand, in the high-frequency module 1a according to Embodiment 2, the chip inductor 614 is connected, in the reception path R4, between the reception filter 14 and the low-noise amplifier 36. That is, in the high-frequency module 1a according to Embodiment 2, the matching circuit 24 provided in the reception path R4 includes the chip inductor 614.

In the high-frequency module 1a according to Embodiment 2, the low-noise amplifier 35 functions both as the low-noise amplifier 30 in the reception path R1 and as the low-noise amplifier 30 in the reception path R2. In the high-frequency module 1a according to Embodiment 2, the low-noise amplifier 36 functions both as the low-noise amplifier 30 in the reception path R3 and as the low-noise amplifier 30 in the reception path R4. Therefore, in the high-frequency module 1a according to Embodiment 2, the number of components can be reduced more than in the high-frequency module 1, so that the high-frequency module 1a can be miniaturized.

In the high-frequency module 1a according to Embodiment 2, the matching circuit 21 is provided between the reception filter 11 and the selection terminal 161 of the second switch 16. In the high-frequency module 1a, the matching circuit 22 is provided between the reception filter 12 and the selection terminal 162 of the second switch 16. In the high-frequency module 1a, the matching circuit 23 is provided between the reception filter 13 and the selection terminal 171 of the third switch 17. In the high-frequency module 1a, the matching circuit 24 is provided between the reception filter 14 and the selection terminal 172 of the third switch 17. Therefore, as in the case of Embodiment 1, any one of the matching circuits 21 to 24 can include the chip inductor 61 and the inner layer inductor 62. Thus, the high-frequency module 1a according to Embodiment 2 has the same effects as the high-frequency module 1 according to Embodiment 1.

### Embodiment 3

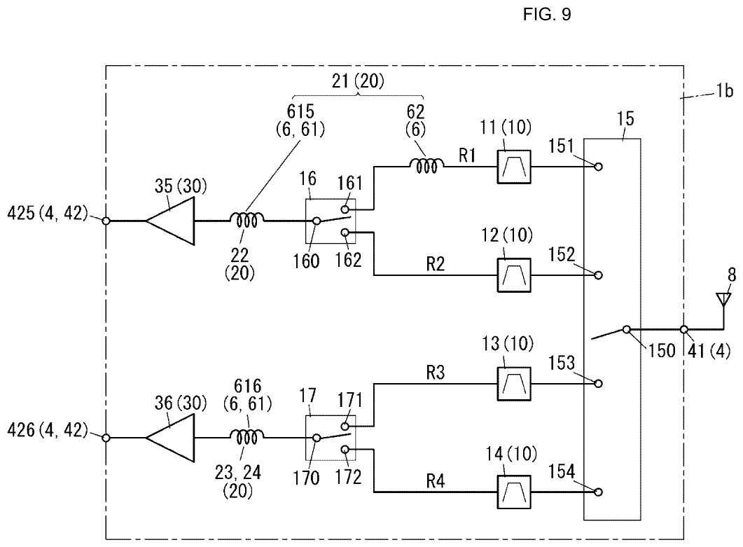

A high-frequency module 1b according to Embodiment 3 will be described with reference to FIG. 9. With respect to the high-frequency module 1b according to Embodiment 3, the same configurations as those of the high-frequency module 1a according to Embodiment 2 (see FIG. 8) are denoted by the same reference signs, and the description thereof will be omitted.

The high-frequency module 1b according to Embodiment 3 includes a chip inductor 615 and a chip inductor 616 as a plurality of chip inductors 61.

The second switch 16 is connected between the reception filters 11 and 12 and the low-noise amplifier 35. The second switch 16 includes a common terminal 160 and selection terminals 161 and 162. The common terminal 160 of the second switch 16 is connected to the chip inductor 615. The selection terminal 161 of the second switch 16 is connected to the inner layer inductor 62. The selection terminal 162 of the second switch 16 is connected to the reception filter 12.

In the high-frequency module 1b according to Embodiment 3, the reception path R1 is a path between the selection terminal 151 of the first switch 15 and the signal output terminal 425. In the high-frequency module 1b according to Embodiment 3, the reception path R2 is a path between the selection terminal 152 of the first switch 15 and the signal output terminal 425. That is, in the high-frequency module 1b according to Embodiment 3, both the reception path R1 and the reception path R2 include a path between the common terminal 160 of the second switch 16 and the signal output terminal 425. The second switch 16 is a switch to switch which of the reception filter 11 and the reception filter 12 is to be connected to the chip inductor 615, the low-noise amplifier 35, and the signal output terminal 425.

In the high-frequency module 1b according to Embodiment 3, the chip inductor 615 and the inner layer inductor 62 are connected, in the reception path R1, between the reception filter 11 and the low-noise amplifier 35. That is, in the high-frequency module 1b according to Embodiment 3, the matching circuit 21 provided in the reception path R1 includes the chip inductor 615 and the inner layer inductor 62. On the other hand, in the high-frequency module 1b according to Embodiment 3, the chip inductor 615 is connected, in the reception path R2, between the reception filter 12 and the low-noise amplifier 35. That is, in the high-frequency module 1b according to Embodiment 3, the matching circuit 22 provided in the reception path R2 includes the chip inductor 615. The inductance of the chip inductor 615 is, for example, 27 nH. The inductance of the inner layer inductor 62 is, for example, 9 nH. Therefore, the inductance of the matching circuit 21 is 36 nH, and the inductance of the matching circuit 22 is 27 nH.

The third switch 17 is connected between the reception filters 13 and 14 and the low-noise amplifier 36. The third switch 17 includes a common terminal 170 and selection terminals 171 and 172. The common terminal 170 of the third switch 17 is connected to the chip inductor 616. The selection terminal 171 of the third switch 17 is connected to the reception filter 13. The selection terminal 172 of the third switch 17 is connected to the reception filter 14.

In the high-frequency module 1b according to Embodiment 3, the reception path R3 is a path between the selection terminal 153 of the first switch 15 and the signal output terminal 426. In the high-frequency module 1b according to Embodiment 3, the reception path R4 is a path between the selection terminal 154 of the first switch 15 and the signal output terminal 426. That is, in the high-frequency module 1b according to Embodiment 3, both the reception path R3 and the reception path R4 include a path between the common terminal 170 of the third switch 17 and the signal output terminal 426. The third switch 17 is a switch to switch which of the reception filter 13 and the reception filter 14 is to be connected to the chip inductor 616, the low-noise amplifier 36, and the signal output terminal 426.

In the high-frequency module 1b according to Embodiment 3, the chip inductor 616 is connected, in the reception path R3, between the reception filter 13 and the low-noise amplifier 36. That is, in the high-frequency module 1b according to Embodiment 3, the matching circuit 23 provided in the reception path R3 includes the chip inductor 616. On the other hand, in the high-frequency module 1b according to Embodiment 3, the chip inductor 616 is connected, in the reception path R4, between the reception filter 14 and the low-noise amplifier 36. That is, in the high-frequency module 1b according to Embodiment 3, the matching circuit 24 provided in the reception path R4 includes the chip inductor 616. The inductance of the chip inductor 616 is, for example, 20 nH. Therefore, the inductance of the matching circuit 23 and the inductance of the matching circuit 24 are both 20 nH.

In the high-frequency module 1b according to Embodiment 3, the chip inductor 615 and the low-noise amplifier 35 function both as the chip inductor 61 and the low-noise amplifier 30 in the reception path R1 and as the chip inductor 61 and the low-noise amplifier 30 in the reception path R2. In the high-frequency module 1b according to Embodiment 3, the chip inductor 616 and the low-noise amplifier 36 function both as the chip inductor 61 and the low-noise amplifier 30 in the reception path R3 and as the chip inductor 61 and the low-noise amplifier 30 in the reception path R4. Therefore, in the high-frequency module 1b according to Embodiment 3, the number of components can be reduced more than in the high-frequency module 1a, so that the high-frequency module 1b can be miniaturized.

In the high-frequency module 1b according to Embodiment 3, the matching circuit 21 includes the inner layer inductor 62. Thus, in the high-frequency module 1b according to Embodiment 3, any one of the matching circuits 21 to 24 can include the chip inductor 61 and the inner layer inductor 62. Therefore, the high-frequency module 1b according to Embodiment 3 has the same effects as the high-frequency module 1 according to Embodiment 1.

### Embodiment 4

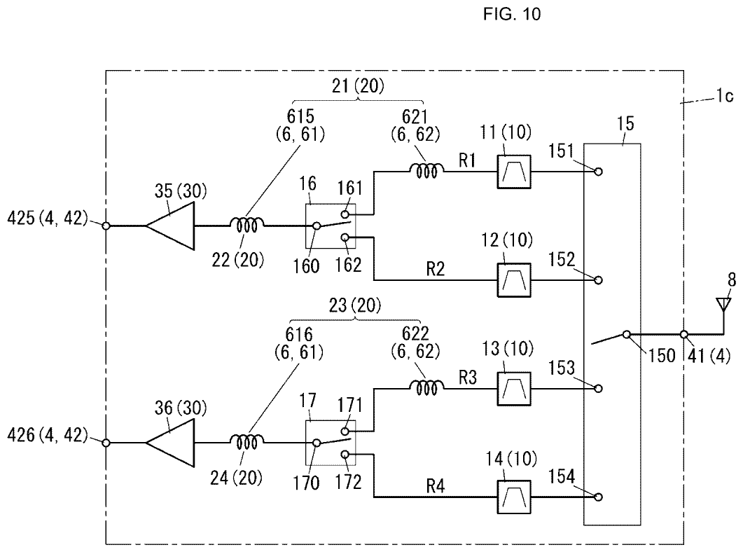

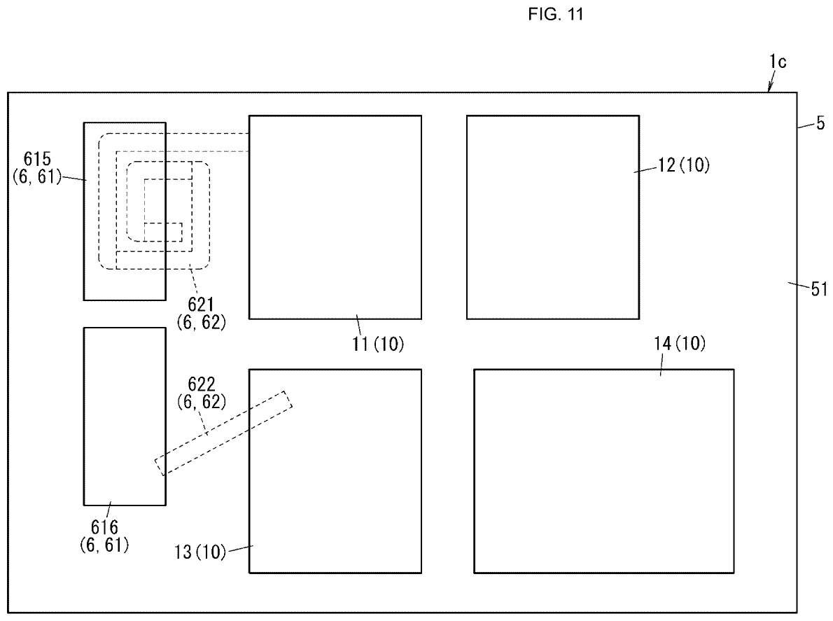

A high-frequency module 1c according to Embodiment 4 will be described with reference to FIGS. 10 and 11. With respect to the high-frequency module 1c according to Embodiment 4, the same configurations as those of the high-frequency module 1 according to Embodiment 1 (see FIG. 2) and the high-frequency module 1c according to Embodiment 3 (see FIG. 9) are denoted by the same reference signs, and the description thereof will be omitted.

### (1) Circuit Configuration of High-Frequency Module

The high-frequency module 1c according to Embodiment 4 includes two chip inductors 615 and 616 and two inner layer inductors 621 and 622 as a plurality of inductors 6.

The second switch 16 is connected between the reception filters 11 and 12 and the low-noise amplifier 35. The second switch 16 includes a common terminal 160 and selection terminals 161 and 162. The common terminal 160 of the second switch 16 is connected to the chip inductor 615. The selection terminal 161 of the second switch 16 is connected to the inner layer inductor 621. The selection terminal 162 of the second switch 16 is connected to the reception filter 12.

In the high-frequency module 1c according to Embodiment 4, the reception path R1 is a path between the selection terminal 151 of the first switch 15 and the signal output terminal 425. In the high-frequency module 1c according to Embodiment 4, the reception path R2 is a path between the selection terminal 152 of the first switch 15 and the signal output terminal 425. That is, in the high-frequency module 1c according to Embodiment 4, both the reception path R1 and the reception path R2 include a path between the common terminal 160 of the second switch 16 and the signal output terminal 425. The second switch 16 is a switch to switch which of the reception filter 11 and the reception filter 12 is to be connected to the chip inductor 615, the low-noise amplifier 35, and the signal output terminal 425.

In the high-frequency module 1c according to Embodiment 4, the chip inductor 615 and the inner layer inductor 62 are connected, in the reception path R1, between the reception filter 11 and the low-noise amplifier 35. That is, in the high-frequency module 1c according to Embodiment 4, the matching circuit 21 provided in the reception path R1 includes the chip inductor 615 and the inner layer inductor 62. On the other hand, in the high-frequency module 1c according to Embodiment 4, the chip inductor 615 is connected, in the reception path R2, between the reception filter 12 and the low-noise amplifier 35. That is, in the high-frequency module 1c according to Embodiment 4, the matching circuit 22 provided in the reception path R2 includes the chip inductor 615. The inductance of the chip inductor 615 is, for example, 27 nH. The inductance of the inner layer inductor 621 is, for example, 9 nH. Therefore, the inductance of the matching circuit 21 is 36 nH, and the inductance of the matching circuit 22 is 27 nH.

The third switch 17 is connected between the reception filters 13 and 14 and the low-noise amplifier 36. The third switch 17 includes a common terminal 170 and selection terminals 171 and 172. The common terminal 170 of the third switch 17 is connected to the chip inductor 616. The selection terminal 171 of the third switch 17 is connected to the inner layer inductor 622. The selection terminal 172 of the third switch 17 is connected to the reception filter 14.

In the high-frequency module 1c according to Embodiment 4, the reception path R3 is a path between the selection terminal 153 of the first switch 15 and the signal output terminal 426. In the high-frequency module 1c according to Embodiment 4, the reception path R4 is a path between the selection terminal 154 of the first switch 15 and the signal output terminal 426. That is, in the high-frequency module 1c according to Embodiment 4, both the reception path R3 and the reception path R4 include a path between the common terminal 170 of the third switch 17 and the signal output terminal 426. The third switch 17 is a switch to switch which of the reception filter 13 and the reception filter 14 is to be connected to the chip inductor 616, the low-noise amplifier 36, and the signal output terminal 426.

In the high-frequency module 1c according to Embodiment 4, the chip inductor 616 and the inner layer inductor 622 are connected, in the reception path R3, between the reception filter 13 and the low-noise amplifier 36. That is, in the high-frequency module 1c according to Embodiment 4, the matching circuit 23 provided in the reception path R3 includes the chip inductor 616 and the inner layer inductor 622. The inner layer inductor 622 includes, for example, a conductive layer and a via conductor (not shown). The conductive layer and the via conductor are formed, for example, in a C-shape when viewed in plan view in a direction orthogonal to the first direction D1 and orthogonal to the extending direction of the conductive layer. On the other hand, in the high-frequency module 1c according to Embodiment 4, the chip inductor 616 is connected, in the reception path R4, between the reception filter 14 and the low-noise amplifier 36. That is, in the high-frequency module 1c according to Embodiment 4, the matching circuit 24 provided in the reception path R4 includes the chip inductor 616. The inductance of the chip inductor 616 is, for example, 18 nH. The inductance of the inner layer inductor 622 is, for example, 4 nH. Therefore, the inductance of the matching circuit 23 is 22 nH, and the inductance of the matching circuit 24 is 18 nH.

### (2) Structure of High-Frequency Module

In the high-frequency module 1c according to Embodiment 4, the plurality of reception filters 10 and the plurality of inductors 6 are disposed on the first main surface 51 of the mounting substrate 5 as shown in FIG. 11. As shown in FIG. 11, the two chip inductors 61 are disposed close to each other. Thus, it is easy to shorten the wiring between each of the plurality of reception filters 10 and the inductor 6 of the matching circuit 20 corresponding to the reception filter 10.

Further, in the high-frequency module 1c according to Embodiment 4, the inner layer inductor 62 and the chip inductor 61 connected to each other are disposed so as to overlap with each other when viewed in plan view in the thickness direction (first direction D1) of the mounting substrate 5. More specifically, at least a part of the inner layer inductor 621 overlaps with at least a part of the chip inductor 615 when viewed in plan view in the first direction D1. At least a part of the inner layer inductor 622 overlaps with at least a part of the chip inductor 616 when viewed in plan view in the first direction D1.

Further, when viewed in plan view in the thickness direction (first direction D1) of the mounting substrate 5, the inner layer inductor 62 and the chip inductor 61 not connected to each other do not overlap with each other. More specifically, when viewed in plan view in the first direction D1, there are no overlapping portions between the inner layer inductor 622 and the chip inductor 615. Also, when viewed in plan view in the first direction D1, there are no overlapping portions between the inner layer inductor 621 and the chip inductor 616.

Thus, the isolation between the reception paths R1 to R4 is improved.

### (3) Effects

In the high-frequency module 1c according to Embodiment 4, the chip inductor 615 and the low-noise amplifier 35 function both as the chip inductor 61 and the low-noise amplifier 30 in the reception path R1 and as the chip inductor 61 and the low-noise amplifier 30 in the reception path R2. Further, in the high-frequency module 1c according to Embodiment 4, the chip inductor 616 and the low-noise amplifier 36 function both as the chip inductor 61 and the low-noise amplifier 30 in the reception path R3 and as the chip inductor 61 and the low-noise amplifier 30 in the reception path R4. Therefore, as in the high-frequency module 1b according to Embodiment 3, the number of components can be reduced more than in high-frequency module 1a, so that the high-frequency module 1c can be miniaturized.

In the high-frequency module 1c according to Embodiment 4, the matching circuit 21 includes the inner layer inductor 621. In the high-frequency module 1c according to Embodiment 4, the matching circuit 23 includes the inner layer inductor 622. Thus, in the high-frequency module 1c according to Embodiment 4, any one of the matching circuits 21 to 24 can include the chip inductor 61 and the inner layer inductor 62. Therefore, the high-frequency module 1c according to Embodiment 4 has the same effects as the high-frequency module 1 according to Embodiment 1.

### (Modifications)

In the high-frequency modules 1 and 1a according to Embodiments 1 and 2, in the matching circuit 21, the inner layer inductor 62 is connected to the reception filter 11 and the chip inductor 61 is connected to the low-noise amplifier 31, but the matching circuit 21 is not limited to such a configuration. For example, the chip inductor 61 may be connected to the reception filter 11 and the inner layer inductor 62 may be connected to the low-noise amplifier 31.

In the high-frequency modules 1 to 1c according to Embodiments 1 to 4, the number of the reception paths R1 to R4 is not limited to four, but may be two, three, five or more than five. In the high-frequency modules 1a to 1c according to Embodiments 2 to 4, the number of the plurality of low-noise amplifiers 30 and the number of the plurality of signal output terminals 42 are not each limited to two, but may each be any number such as one.

The high-frequency modules 1 to 1c according to Embodiments 1 to 4 may have one or more transmission paths. The transmission path includes, for example, a transmission filter and a power amplifier.

The communication device 100 according to the Embodiment 1 may include any of the high-frequency modules 1a, 1b, and 1c instead of the high-frequency module 1.

In this description, the expression “an element is disposed on a first main surface of a substrate” includes not only a case where the element is mounted directly on the first main surface of the substrate, but also a case where the element is disposed on, out of a space on the first main surface side and a space on a second main surface side, both being separated from each other by the substrate, the space on the first main surface side. That is, the expression “an element is disposed on a first main surface of a substrate” includes a case where the element is mounted on the first main surface of the substrate with another circuit element, electrode, or the like interposed therebetween. The element is, for example, the reception filter 10, but is not limited to the reception filter 10. The substrate is, for example, the mounting substrate 5. When the substrate is the mounting substrate 5, the first main surface is the first main surface 51, and the second main surface is the second main surface 52.

In this description, the expression “an element is disposed on a second main surface of a substrate” includes not only a case where the element is mounted directly on the second main surface of the substrate, but also a case where the element is disposed on, out of a space on a first main surface side and a space on the second main surface side, both being separated from each other by the substrate, the space on the second main surface side. That is, the expression “an element is disposed on the second main surface of a substrate” includes a case where the element is mounted on the second main surface of the substrate with another circuit element, electrode, or the like interposed therebetween. The element is, for example, the IC chip 7, but is not limited to the IC chip 7. The substrate is, for example, the mounting substrate 5. When the substrate is the mounting substrate, the first main surface is the first main surface 51, and the second main surface is the second main surface 52.

### (Aspects)

The following aspects are disclosed in this description.

A high-frequency module (1; 1a; 1b; 1c) according to a first aspect includes: a mounting substrate (5), a plurality of reception filters (10), a plurality of matching circuits (20), and at least one low-noise amplifier (30). The plurality of reception filters (10) are disposed respectively in a plurality of reception paths (R1 to R4). The plurality of matching circuits (20) are disposed respectively in the plurality of reception paths (R1 to R4), each matching circuit (20) including an inductor (6). At least one low-noise amplifier (30) is connected to each of the plurality of reception paths (R1 to R4). In each of the plurality of reception paths (R1 to R4), the plurality of reception filters (10) and at least one low-noise amplifier (30) are connected to each other with the plurality of matching circuits (20) disposed in the reception paths (R1 to R4) interposed therebetween. At least one of the matching circuits (20) includes a chip inductor (61) and an inner layer inductor (62) among the plurality of inductors (6). The chip inductor (61) is disposed on the mounting substrate (5). The inner layer inductor (62) is built in the mounting substrate (5).

In the high-frequency module (1; 1a; 1b; 1c) according to the above aspect, at least one of the plurality of matching circuits (20) includes, inductors (6), the chip inductor (61) and the inner layer inductor (62). Therefore, according to the high-frequency module (1; 1a; 1b; 1c), the resistance value of the matching circuit (20) can be reduced without increasing the size of the chip inductor (61). Therefore, both miniaturization of the high-frequency module (1; 1a; 1b; 1c) and reduction of the noise factor of the low-noise amplifier (30) can be achieved.

A high-frequency module (1; 1a; 1b; 1c) according to a second aspect is the high-frequency module (1; 1a; 1b; 1c) according to first aspect, in which, among the plurality of matching circuits (20), a matching circuit (21) having the largest inductance includes the chip inductor (61) and the inner layer inductor (62).

With the high-frequency module (1; 1a; 1b; 1c) according to the above aspect, a chip inductor (61) having a small inductance can be used for, among the plurality of matching circuits (20), the matching circuit (20) having the largest inductance. Therefore, by suppressing the size of the chip inductor (61), the high-frequency module (1; 1a; 1b; 1c) can be further miniaturized.

A high-frequency module (1; 1a; 1b; 1c) according to a third aspect is the high-frequency module (1; 1a; 1b; 1c) according to the first or second aspect, in which, among the plurality of matching circuits (20), the matching circuit (21) disposed in a reception path (R1) through which a signal having the lowest frequency passes includes the chip inductor (61) and the inner layer inductor (62).

With the high-frequency module (1; 1a; 1b; 1c) according to the above aspect, the chip inductor (61) having a small inductance can be used for the matching circuit (21) provided in, among the plurality of reception paths (R1 to R4), the reception path (R1) through which the signal with the lowest frequency passes, which tends to have a large inductance of the matching circuit (20). Therefore, by suppressing the size of the chip inductor (61), the high-frequency module (1; 1a; 1b; 1c) can be further miniaturized.

A high-frequency module (1; 1a; 1b; 1c) according to a fourth aspect is the high-frequency module (1; 1a; 1b; 1c) according to any of the first to third aspects, in which the inductance of the chip inductor (611) is equal to or less than the inductance of the inductor (612) included in a matching circuit (22) different from the matching circuit (21) including the chip inductor (611).

With the high-frequency module (1; 1a; 1b; 1c) according to the above aspect, the resistance value of the matching circuit (21) including the chip inductor (61) and the inner layer inductor (62) is less likely to be larger than the resistance value of the other matching circuit (22). Therefore, in any of the plurality of reception paths (R1 to R4), the increase of the resistance value of the matching circuit (20) can be suppressed, and the deterioration of the noise factor of the low-noise amplifier (30) can be suppressed.

A high-frequency module (1; 1a; 1b; 1c) according to a fifth aspect is the high-frequency module (1; 1a; 1b; 1c) according to any of the first to fourth aspects, in which the chip inductor (611; 615; 616) and the inner layer inductor (62; 621; 622) overlap with each other when viewed in plan view in the thickness direction (D1) of the mounting substrate (5).

In the high-frequency module (1; 1a; 1b; 1c) according to the above aspect, the chip inductor (61) and the inner layer inductor (62) included in one matching circuit (20) are disposed physically close to each other. Therefore, the electromagnetic coupling between the inner layer inductor (62) and the inductor (6) included in the other matching circuit (20) can be reduced. Further, since the area occupied by the chip inductor (61) and the inner layer inductor (62) on the first main surface (51) of the mounting substrate (5) can be reduced, the high-frequency module (1; 1a; 1b; 1c) can be miniaturized.

A high-frequency module (1; 1a; 1b; 1c) according to a sixth aspect is the high-frequency module (1; 1a; 1b; 1c) according to the fifth aspect, in which the inner layer inductor (62) does not overlap with the inductor (6) of the matching circuit (20) different from the matching circuit (21) including the inner layer inductor (62) when viewed in plan view in the thickness direction (D1) of the mounting substrate (5).

With the high-frequency module (1; 1a; 1b; 1c) according to the above aspect, the electromagnetic coupling between the inner layer inductor (62) and the inductor (6) included in the other matching circuit (20) can be reduced. Therefore, the isolation between each of the reception paths (R1 to R4) of the high-frequency module (1; 1a; 1b; 1c) is improved.

A high-frequency module (1; 1a; 1b; 1c) according to a seventh aspect is the high-frequency module (1; 1a; 1b; 1c) according to any of the first to sixth aspects, in which the inductance of the chip inductor (611) is larger than the inductance of the inner layer inductor (62).

With the high-frequency module (1; 1a; 1b; 1c) according to the above aspect, the increase of the resistance value of the matching circuit (21) can be reduced by reducing the increase of the resistance value of the inner layer inductor (62). Therefore, the deterioration of the noise factor of the low-noise amplifier (31) connected to the matching circuit (21) can be reduced.

A high-frequency module (1; 1a; 1b; 1c) according to an eighth aspect is the high-frequency module (1; 1a; 1b; 1c) according to any of the first to seventh aspects, in which the mounting substrate (5) has a first main surface (51) and a second main surface (52) facing each other. The plurality of inductors (6) of the plurality of matching circuits (20) are disposed close to each other on the first main surface (51) of the mounting substrate (5), e.g., without other electronic components disposed therebetween.

With the high-frequency module (1; 1a; 1b; 1c) according to the above aspect, the variation of the wiring length between the inductor (6) and the low-noise amplifier (30) in the reception paths (R1 to R4) can be reduced, and the wiring length can be reduced. Therefore, with the high-frequency module (1; 1a; 1b; 1c), the resistance value of the matching circuit (20) can be reduced, and the deterioration of the noise factor of the low-noise amplifier (30) can be reduced.

A high-frequency module (1; 1a; 1b; 1c) according to a ninth aspect is the high-frequency module (1; 1a; 1b; 1c) according to the eighth aspect, in which the plurality of reception filters (10) are disposed, on the first main surface (51) of the mounting substrate (5), between the end of the mounting substrate (5) and the plurality of inductors (6).

With the high-frequency module (1; 1a; 1b; 1c) according to the above aspect, it is easy to reduce the wiring length between the inductor (6) and the reception filter (10). Therefore, with the high-frequency module (1; 1a; 1b; 1c), the resistance value of the matching circuit (20) can be reduced, and the deterioration of the noise factor of the low-noise amplifier (30) can be reduced.

A high-frequency module (1; 1a; 1b; 1c) according to a tenth aspect is the high-frequency module (1; 1a; 1b; 1c) according to the eighth or ninth aspect, in which at least one low-noise amplifier (30) is included in one IC chip (7) disposed on the second main surface (52) of the mounting substrate (5). When viewed in a plan view in the thickness direction (D1) of the mounting substrate (5), at least a part of the inductors (6) of the plurality of matching circuits (20) overlaps with at least a part of the IC chip (7).

With the high-frequency module (1; 1a; 1b; 1c) according to the above aspect, it is easy to reduce the wiring length between the inductor (6) and the low-noise amplifier (30). Therefore, with the high-frequency module (1; 1a; 1b; 1c), the resistance value of the matching circuit (20) can be reduced, and the deterioration of the noise factor of the low-noise amplifier (30) can be reduced.

A communication device (100) according to an eleventh aspect includes: the high-frequency module (1; 1a; 1b; 1c) according to any of the first to tenth aspects; and a signal processing circuit (9). The signal processing circuit (9) is connected to the high-frequency module (1; 1a; 1b; 1c).

In the communication device (100) according to the above aspect, in the high-frequency module (1; 1a; 1b; 1c), at least one of the plurality of matching circuits (20) includes, as the inductor (6), a chip inductor (61) and an inner layer inductor (62). Therefore, with the high-frequency module (1; 1a; 1b; 1c), the resistance value of the matching circuit (20) can be reduced without increasing the size of the chip inductor (61). Therefore, both miniaturization of the high-frequency module (1; 1a; 1b; 1c) and reduction of the noise factor of the low-noise amplifier (30) in the plurality of reception paths (R1 to R4) can be achieved.

### REFERENCE SIGNS LIST

100 communication device
1, 1a, 1b, 1c high-frequency module
10, 11 to 14 reception filter
15 switch, first switch
150 common terminal
151 to 154 selection terminal
16 second switch
160 common terminal
161, 162 selection terminal
17 third switch
170 common terminal
171, 172 selection terminal
20, 21 to 24 matching circuit
30, 31 to 36 low-noise amplifier
4 external connection terminal
41 antenna terminal
42 signal output terminal
421 to 426 signal output terminal
5 mounting substrate
51 first main surface
52 second main surface
6 inductor
61 chip inductor
611 to 616 chip inductor
62 inner layer inductor
621, 622 inner layer inductor
7 IC chip
8 antenna
9 signal processing circuit
1 first direction
R1 to R4 reception path

1. A high-frequency module, comprising:
a mounting substrate;
a plurality of reception paths, each including a reception filter and a matching circuit; and
at least one low-noise amplifier connected to each of the plurality of reception paths,
wherein
in each of the plurality of reception paths, a respective one of the reception filters is connected to the at least one low-noise amplifier through a respective matching circuit, and
the inductor of at least one of the matching circuits includes a chip inductor disposed on the mounting substrate and an inner layer inductor built in the mounting substrate.

2. The high-frequency module according to claim 1, wherein, among the matching circuits, a matching circuit having the largest inductance includes the chip inductor and the inner layer inductor.

3. The high-frequency module according to claim 1, wherein, among the matching circuits, a matching circuit disposed in a reception path through which a signal having the lowest frequency passes includes the chip inductor and the inner layer inductor.

4. The high-frequency module according to claim 1, wherein an inductance of the chip inductor is equal to or less than an inductance of an inductor included in a different matching circuit from the matching circuit including the chip inductor.

5. The high-frequency module according to claim 1, wherein the chip inductor and the inner layer inductor of the at least one of the matching circuits overlap with each other when viewed in plan view along a thickness direction of the mounting substrate.

6. The high-frequency module according to claim 5, wherein the inner layer inductor does not overlap with an inductor of a different matching circuit from the at least one of the matching circuits when viewed in a plan view in the thickness direction of the mounting substrate.

7. The high-frequency module according to claim 1, wherein the inductance of the chip inductor is larger than the inductance of the inner layer inductor in the least one of the matching circuits.

8. The high-frequency module according to claim 1, wherein
the mounting substrate has a first main surface and a second main surface facing each other, and
the inductors of the matching circuits are disposed close to each other on the first main surface of the mounting substrate.

9. The high-frequency module according to claim 8, wherein the inductors on the first main surface of the mounting substrate are chip inductors.

10. The high-frequency module according to claim 8, wherein the reception filters are disposed on the first main surface of the mounting substrate between an end of the mounting substrate and the inductors.

11. The high-frequency module according to claim 8, wherein
the at least one low-noise amplifier is included in a single integrated circuit (IC) chip disposed on the second main surface of the mounting substrate, and
when viewed in the plan view in the thickness direction of the mounting substrate, each inductor of the plurality of reception paths overlap the IC chip.

12. The high-frequency module according to claim 11, wherein the inductors on the first main surface of the mounting substrate are chip inductors.

13. The high-frequency module according to claim 12, wherein the inner layer inductor of the at least one matching circuit, when viewed in the plan view in the thickness direction of the mounting substrate, overlaps the IC chip.

14. The high-frequency module according to claim 1, wherein the chip inductor of the at least one of the plurality of matching circuits is shared by a second of the plurality of matching circuits, and wherein the inner layer inductor is in only a first of the plurality of reception paths.

15. The high-frequency module according to claim 1, wherein the chip inductor and the inner layer inductor of the at least one of matching circuits are connected in series.

16. The high-frequency module according to claim 1, further comprising a first switch having a common terminal connected to an antenna terminal and a plurality of selection terminals, wherein each selection terminal is connected to a respective one of the reception filters.

17. The high-frequency module according to claim 16, further comprising a second switch configured to selectively connect outputs of at least two of the matching circuits to a single low-noise amplifier of the at least one low-noise amplifier.

18. The high-frequency module according to claim 1, wherein the inductance of the chip inductor is at least double the inductance of the inner layer inductor.

19. A communication device comprising:
the high-frequency module according to claim 1; and
a signal processing circuit connected to the high-frequency module configured to process signals from the at least one low-noise amplifier.

20. A high-frequency module, comprising:
a multilayer substrate having a first surface and a second surface;
a plurality of reception filters and a plurality of surface-mount chip inductors disposed on the first surface;
a plurality of low-noise amplifiers; and
at least one inner layer inductor disposed within the multilayer substrate;
wherein the at least one inner layer inductor is electrically connected to at least one of the plurality of surface-mount chip inductors to form a matching circuit for a first reception path, the matching circuit being coupled between one of the reception filters and one of the low-noise amplifiers; and
wherein a second reception path includes a second of the plurality of surface-mount chip inductors as a matching circuit inductor without an associated inner layer inductor.
